(19) United States
(12) Patent Application Publication
(10) Pub. No.: US 2012/0068224 A1
(43) Pub. Date: Mar. 22, 2012

(54) METHOD OF PRODUCING SEMICONDUCTOR WAFER, AND SEMICONDUCTOR WAFER

(75) Inventors: Naohiro NISHIKAWA, Ichihara-shi (JP); Tsuyoshi NAKANO, Sodegaura-shi (JP); Takayuki INOUE, Toda-shi (JP)

(73) Assignee: SUMITOMO CHEMICAL COMPANY, LIMITED, Tokyo (JP)

(21) Appl. No.: 13/267,370

(22) Filed: Oct. 6, 2011

Related U.S. Application Data
(63) Continuation-in-part of application No. PCT/JP2010/002450, filed on Apr. 2, 2010.

(30) Foreign Application Priority Data
Apr. 7, 2009 (JP) 2009-093443

(51) Int. Cl. H01L 29/36; H01L 21/02; H01L 21/20

(52) U.S. Cl. 257/183; 438/478; 438/382; 257/E29.109; 257/E21.004; 257/E21.09

(57) ABSTRACT

A method of producing a semiconductor wafer suited to form types of devices such as HBT and FET on a single semiconductor wafer is provided. The method, by repeating steps including introducing, into a reaction chamber for forming a semiconductor by crystal growth, a first-impurity gas containing an element or a compound containing a first impurity atom as a constituent, thereby producing semiconductor wafers, includes, after introducing the first-impurity gas: taking out a produced semiconductor wafer; disposing a first semiconductor in the reaction chamber; introducing, into the reaction chamber, a second-impurity gas containing an element or a compound containing, as a constituent, a second impurity atom exhibiting a conduction type opposite to the conduction type of the first impurity atom within the first semiconductor; heating the first semiconductor in an atmosphere of the second-impurity gas; and forming a second semiconductor on the heated first semiconductor by crystal growth.

The contents of the following Japanese patent application and PCT patent application are incorporated herein by reference:
JP2009-093443 filed on Apr. 7, 2009, and
PCT/JP2010/002450 filed on Apr. 2, 2010.

### TECHNICAL FIELD

The present invention relates to a method of producing a semiconductor wafer, and a semiconductor wafer.

### BACKGROUND ART

Patent Document 1 discloses a method of producing a Group 3-5 compound semiconductor epitaxial wafer suited for making integrated activating devices (e.g., HBT and FET) having at least two different types on a wafer.
Patent Document 1: JP2008-60554 A

### SUMMARY OF THE INVENTION

### Problems to be Solved by the Invention

When forming, on a single semiconductor wafer, a plurality of different types of devices, e.g., hetero junction bipolar transistor (hereinafter referred to as HBT) and field effect transistor (hereinafter referred to as FET), the production process of one device occasionally influences the production process of the other device.

For example, when there remains an impurity (e.g., Si) introduced as a dopant in HBT into a reaction chamber used for producing one device, this impurity may occasionally attach to diffuse on the semiconductor wafer of another device subsequently produced. The impurity creates a carrier on the FET formed on the semiconductor wafer, which may lead to cause leak current. Generation of a carrier may also make the device isolation between the devices instable, or make it difficult to optimize the characteristics of the both devices formed on a single semiconductor wafer.

### Means for Solving the Problems

For a solution to the above-mentioned problems, according to the first aspect related to the present invention, provided is a method of producing a semiconductor wafer, by repeating steps including introducing, into a reaction chamber for forming a semiconductor by crystal growth, a first impurity gas containing an element or a compound containing a first impurity atom as a constituent, thereby producing a plurality of semiconductor wafers, the method including, after introducing the first impurity gas: taking out a produced semiconductor wafer; disposing a first semiconductor in the reaction chamber; introducing, into the reaction chamber, a second impurity gas containing an element or a compound containing, as a constituent, a second impurity atom that exhibits a conduction type opposite to the conduction type of the first impurity atom within the first semiconductor; heating the first semiconductor in an atmosphere of the second impurity gas; and forming a second semiconductor on the heated first semiconductor by crystal growth.

The condition under which the first semiconductor is heated may be set so that an effective carrier density representing the difference between the electron density and the hole density may be decreased at least on the surface of the first semiconductor. In the method of producing, the first impurity atom may be an impurity atom that exhibits a conduction type of N within the first semiconductor, and the second impurity gas may include a P-type impurity gas containing an impurity atom that exhibits a conduction type of P within the first semiconductor. In the production method, it is also possible that the first semiconductor or the second semiconductor be a Group 3-5 compound semiconductor, and the P-type impurity gas contain a halogenated hydrocarbon gas.

In an example, the halogenated hydrocarbon gas is CHₙX₍₄₋ₙ₎, where “X” is a halogen atom selected from the group consisting of Cl, Br, and I, and “n” is an integer satisfying 0≦n≦3, and when 0≦n≦2, the Xs are identical atoms or different atoms. In the production method, the first semiconductor or the second semiconductor may be a Group 3-5 compound semiconductor, and the second impurity gas may contain arsine and hydrogen. In the production method, it is also possible that the second impurity gas contain an arsine source gas containing 1 ppb or less of GeH₄.

In one example, the second semiconductor is a monocarrier movement semiconductor that functions as a channel through which an electron or a hole moves. In the method of manufacturing, the monocarrier movement semiconductor may be an N-type monocarrier movement semiconductor of a Group 3-5 compound semiconductor, and when forming the second semiconductor by crystal growth, the N-type monocarrier movement semiconductor may be formed by crystal growth by introducing, into the reaction chamber, silane or disilane as a compound containing an impurity atom that exhibits the conduction type of N. The production method may further include: forming, on the second semiconductor, a monocarrier movement semiconductor having a conduction type opposite to the conduction type of the second semiconductor.

In addition, the production method may further include: forming a stacked semiconductor represented by N-type semiconductor/P-type semiconductor/NI-type semiconductor, or a stacked semiconductor represented by P-type semiconductor/N-type semiconductor/P-type semiconductor, either by forming the N-type semiconductor, the P-type semiconductor, and the N-type semiconductor in the stated order by the epitaxial growth method on the second semiconductor, or by forming the P-type semiconductor, the N-type semiconductor, and the P-type semiconductor in the stated order by the epitaxial growth method on the second semiconductor.

In this case, it is possible to have such a configuration that the first impurity atom is an impurity atom that exhibits a conduction type of N within the semiconductor, the second impurity gas includes a P-type impurity gas containing a P-type impurity atom that exhibits a conduction type of P, the stacked semiconductor includes a base layer that functions as a base of a bipolar transistor, and the base layer is produced by introducing a gas of the same type as the P-type impurity gas into the reaction chamber. In addition, when forming the second semiconductor by crystal growth, the N-type semiconductor may be formed in the stacked semiconductor by introducing, into the reaction chamber, silane or disilane as a compound containing an impurity atom that exhibits the conduction type of N.

The step of forming the resistor may include: forming a P-type semiconductor of a Group 3-5 compound semiconductor by epitaxial growth using a Group 3 source gas containing a Group 3 element and a Group 5 source gas containing a Group 5 element, and when forming the P-type semiconductor, the acceptor concentration of the P-type semiconductor may be controlled by the flow rate ratio of the Group 3 source gas to the Group 5 source gas. The production method may further include, after forming at least the second semiconductor on the first semiconductor: taking out, from the reaction chamber, the semiconductor wafer on which at least the second semiconductor has been formed, where after taking out the semiconductor wafer, 1) disposing another first semiconductor different from the first semiconductor inside the reaction chamber, and introducing the gas into the reaction chamber, 2) heating the another first semiconductor in an atmosphere of the gas, and 3) forming the second semiconductor on the heated first semiconductor are repeated without conducting a process for alleviating an effect of the impurity atom in the reaction chamber.

According to the second aspect related to the present invention, provided is a semiconductor wafer including a first semiconductor and a second semiconductor formed on the first semiconductor, the semiconductor wafer including: a P-type impurity atom and an N-type impurity atom in substantially the same density as the P-type impurity atom, on an interface between the first semiconductor and the second semiconductor. In an example, the P-type impurity atom and the N-type impurity atom may have been activated.

Note that in the present specification, such expressions as “B on A” includes both of a case in which B is in contact with A, and a case in which another component is interposed between B and A.

### BRIEF DESCRIPTION OF THE DRAWINGS

FIG. 1 shows a flowchart showing an example of the method of producing a semiconductor wafer.

FIG. 2 shows an example of a cross section of a semiconductor wafer 200.

FIG. 3 shows an example of a cross section of a semiconductor wafer 300.

FIG. 4 shows an example of a cross section of a semiconductor wafer 1400.

FIG. 5 shows an example of a cross section of a semiconductor wafer 400.

FIG. 6 shows an example of a cross section of a semiconductor wafer 1600.

FIG. 7 shows a flowchart showing an example of the method of producing a semiconductor wafer.

FIG. 8 shows an example of a cross section of a semiconductor wafer 600.

FIG. 9 shows a flowchart showing an example of the method of producing a semiconductor wafer 800.

FIG. 10 shows an example of a cross section of a semiconductor wafer 800.

FIG. 11 shows a flowchart showing an example of the method of producing a semiconductor wafer 200.

FIG. 12 shows a flowchart showing an example of the method of producing a semiconductor wafer 1100.

FIG. 13 shows an example of a cross section of a semiconductor wafer 1100.

### MODE FOR CARRYING OUT THE INVENTION

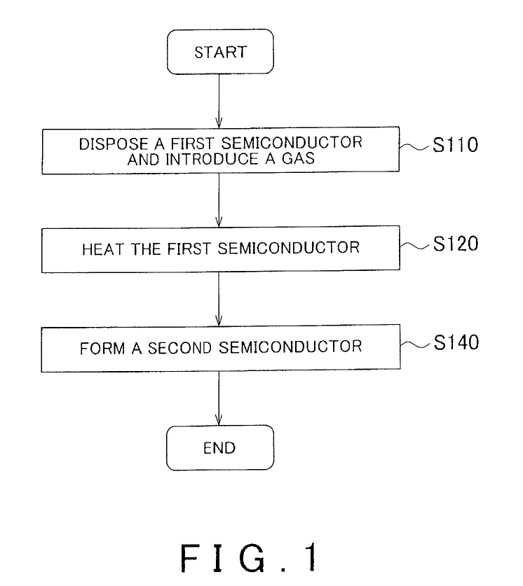

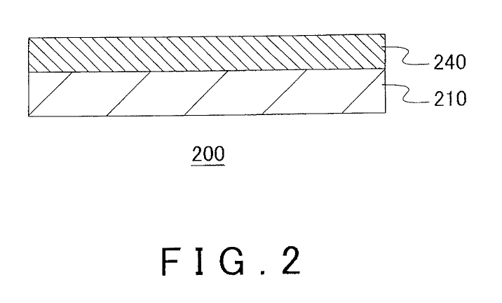

FIG. 1 shows a flowchart showing an example of the method of producing a semiconductor wafer. The present production method includes Step S110 of disposing a first semiconductor and introducing a gas, Step S120 of heating the first semiconductor, and Step S140 of forming a second semiconductor. Note that FIG. 2 shows an example of a cross section of a semiconductor wafer 200 produced according to the production method according to the present embodiment. The semiconductor wafer 200 includes a first semiconductor 210 and a second semiconductor 240.

An electronic element can be formed on the semiconductor wafer 200. For example, the semiconductor wafer 200 may be used to produce an FET, a high electron mobility transistor (occasionally referred to as HEMT), an HBT, or the like.

For example, the first semiconductor 210 is a wafer having sufficient mechanical strength for supporting the other constituents of the semiconductor wafer 200. Some examples of the first semiconductor 210 are a Si wafer, an SOI (silicon-on-insulator) wafer, a Ge wafer, a GOI (germanium-on-insulator) wafer, and a GaAs wafer. An example of the Si wafer is a single crystal Si wafer. The first semiconductor 210 may be a sapphire wafer, a glass wafer, and a resin wafer such as a PET film. The first semiconductor 210 may be a wafer itself, or may be a semiconductor wafer formed by the epitaxial growth method on the wafer. An example of the first semiconductor 210 is a Group 3-5 compound semiconductor.

The second semiconductor 240 is a compound semiconductor capable of forming an electronic element. Some examples of the second semiconductor 240 are a Group 3-5 compound semiconductor and a Group 2-6 compound semiconductor. An example of the second semiconductor 240 is a monocarrier movement semiconductor. A monocarrier movement semiconductor is a semiconductor that functions as a channel of an electronic element such as a transistor, due to movement of one of an electron and a hole.

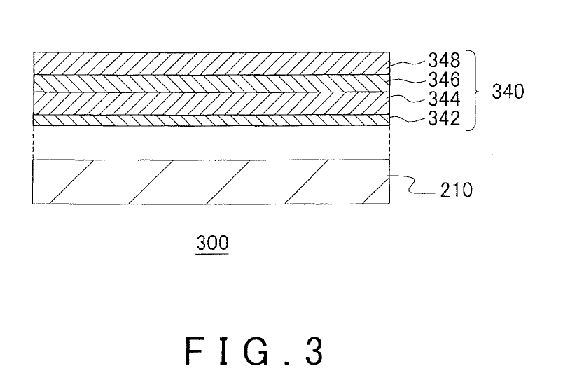

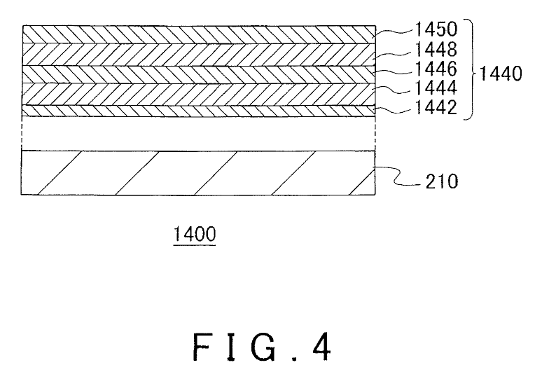

The second semiconductor 240 formed on the first semiconductor 210 may be a single layer or a multi layer, as shown in FIG. 2. FIG. 3 and FIG. 4 are examples in which a second semiconductor 340 and a second semiconductor 1440, being multiple layers, are respectively formed on the first semiconductor 210. When the second semiconductor is made of multiple layers, the multiple layers may be sequentially formed.

In the semiconductor wafer 300 shown in FIG. 3, the second semiconductor 340 includes a second semiconductor 342, a second semiconductor 344, a second semiconductor 346, and a second semiconductor 348. For example, the semiconductor wafer 300 may be a semiconductor wafer suited for HEMT. For example, the second semiconductor 342 is a monocarrier movement semiconductor forming a channel of the HEMT. The second semiconductor 344 is a carrier-supplying semiconductor that supplies a carrier to the second semiconductor 342.

For example, the second semiconductor 346 is a barrier-forming semiconductor with which a gate electrode is formed. For example, the second semiconductor 348 is a contact semiconductor with which a source electrode and a drain electrode are formed. In FIG. 3, the semiconductor wafer 300 may include the other semiconductors or the like in the region shown with the dotted lines. For example, the semiconductor wafer 300 includes a carrier-supplying layer, a spacer layer, a buffer layer, or the like, in the region shown with the dotted lines.

In the semiconductor wafer 1400 shown in FIG. 4, the second semiconductor 1440 includes a second semiconductor 1442, a second semiconductor 1444, a second semiconductor 1446, a second semiconductor 1448, and a second semiconductor 1450. For example, the second semiconductor 1400 is a semiconductor wafer suited for a complementary FET. The second semiconductor 1442 is a monocarrier movement semiconductor forming a channel of the FET. The second semiconductor 1444 is a carrier-supplying semiconductor that supplies a carrier to the second semiconductor 1442.

For example, the second semiconductor 1446 is a barrier-forming semiconductor with which a gate electrode is formed. For example, the second semiconductor 1448 is a contact layer with which a source electrode and a drain electrode are formed. The second semiconductor 1450 is a semiconductor having a conduction type that is opposite to the conduction type of the second semiconductor 1444. In FIG. 4, the semiconductor wafer 1400 may include the other semiconductors or the like in the region shown with the dotted lines. For example, the semiconductor wafer 1400 includes a carrier-supplying layer, a spacer layer, a buffer layer, or the like, in the region shown with the dotted lines.

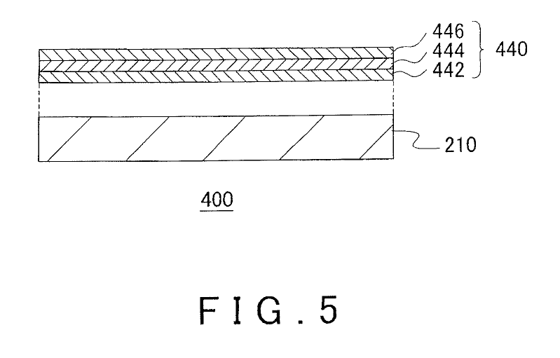

In the semiconductor wafer 400 shown in FIG. 5, the second semiconductor 440 includes a second semiconductor 442, a second semiconductor 444, and a second semiconductor 446. For example, the second semiconductor 400 is a semiconductor wafer suited for an HBT. In an example, the second semiconductor 442 is a collector layer of the HBT. In another example, the second semiconductor 444 is a base layer of the HBT. In a still different example, the second semiconductor 446 is an emitter layer of the HBT. In FIG. 5, the semiconductor wafer 400 may include the other semiconductors or the like in the region shown with the dotted lines. For example, the semiconductor wafer 400 includes a buffer layer, or the like, in the region shown with the dotted lines.

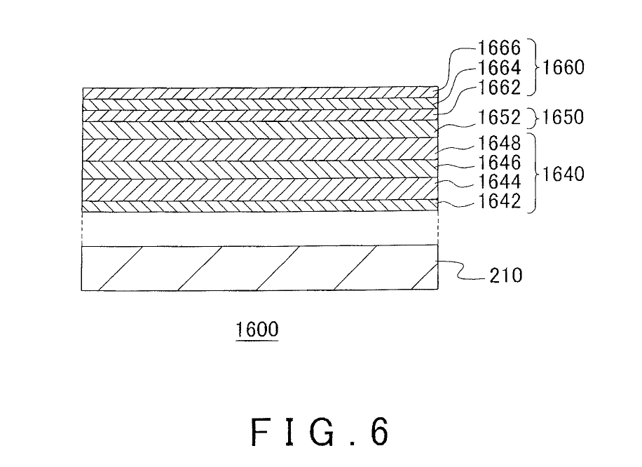

The semiconductor wafer 1600 shown in FIG. 6 includes a stacked semiconductor 1640, a stacked semiconductor 1650, and a stacked semiconductor 1660.

The stacked semiconductor 1640 includes a second semiconductor 1642, a second semiconductor 1644, a second semiconductor 1646, and a second semiconductor 1648. For example, the second semiconductor 1642 is a monocarrier movement semiconductor forming a channel of the FET. The second semiconductor 1644 is a carrier-supplying semiconductor that supplies a carrier to the second semiconductor 1642. For example, the second semiconductor 1646 is a barrier-forming semiconductor with which a gate electrode is formed. For example, the second semiconductor 1648 is a contact layer with which a source electrode and a drain electrode are formed.

The stacked semiconductor 1650 is a semiconductor 1652 having a conduction type that is opposite to the conduction type of the second semiconductor 1644. The stacked semiconductor 1660 includes at least a collector layer 1662, a base layer 1664, and an emitter layer 1666.

The semiconductor wafer 1600 in FIG. 6 may include the other semiconductors or the like in the region shown with the dotted lines. For example, the semiconductor wafer 1600 includes a carrier-supplying layer, a spacer layer, a buffer layer, or the like, in the region shown with the dotted lines.

The following shows an example of the method of producing the semiconductor wafer 200. First of all, in Step S110 of disposing a first semiconductor 210 and introducing a gas, the first semiconductor 210 is disposed in a reaction chamber. The reaction chamber may occasionally contain, prior to starting the production process, a first impurity atom exhibiting a conduction type of P or N within the semiconductor. For example, prior to disposing the first semiconductor 210, a first impurity gas containing an element or a compound that contains a first impurity atom as a constituent is introduced in the reaction chamber, to produce a different semiconductor wafer 200 in the reaction chamber.

In such a case, in the reaction chamber, there occasionally remains a first impurity atom exhibiting a conduction type of N or a first impurity atom exhibiting a conduction type of P, originally contained in the first impurity gas. When such first impurity atoms attach to diffuse on the surface of the first semiconductor 210 of the semiconductor wafer 200 subsequently produced, the first impurity atoms start functioning as a carrier of the second semiconductor 240. As a result, leak current is caused between the first semiconductor 210 and the second semiconductor 240.

In view of this, so as to prevent generation of leak current, the first semiconductor 210 is disposed after taking out the semiconductor wafer 200 produced first. Subsequently, a second impurity gas containing an element or a compound that contains, as a constituent, a second impurity atom which exhibits a conduction type that is opposite to the conduction type of the first impurity atom within the semiconductor is introduced into the reaction chamber. For example, when the first impurity atoms remaining in the reaction chamber are impurity atoms exhibiting a conduction type of N within the semiconductor, the second impurity gas contains a gas containing an element or a compound that contains a second impurity atom exhibiting a conduction type of P as a constituent. The compound including the second impurity atom as a constituent may be a halogenated hydrocarbon, for example. Note that the second impurity gas may be introduced into the reaction chamber, prior to disposing the first semiconductor 210.

For example, a halogenated hydrocarbon gas is CHₙX₍₄₋ₙ₎ (Note that “X” is a halogen atom selected from the group consisting of Cl, Br, and I, and “n” is an integer satisfying 0≦n≦3, and when 0≦n≦2, the Xs may be the identical atoms or different atoms). For example, the compound including a second impurity atom exhibiting a conduction type of P may be CCl₃Br. When the second impurity gas contains halogen, the first impurities remaining in the reaction chamber will be inactivated.

For example, the second impurity gas contains arsine (AsH₃) and hydrogen. Preferably, arsine does not substantially contain remaining Group 4 impurity atom. Specifically, GeH₄ contained in the arsine source gas contained in the second impurity gas may be 1 ppb or below.

Prior to introducing the second impurity gas after disposing the first semiconductor 210, the reaction chamber may be vacuumed. Prior to introducing the second impurity gas, the reaction chamber may be purged using a nitrogen gas, a hydrogen gas, an inert gas, or the like. The second impurity gas may be introduced prior to the subsequent Step S120 of heating or during the heating step, or may be exchanged during the heating step.

The second impurity gas may be one type of gas, or may be a mixture of a plurality of types of gasses. For example, as a second impurity gas, a gas containing an element or a compound that contains an impurity atom exhibiting a conduction type of P as a constituent may be introduced alone. The gas containing an element or a compound that contains an impurity atom exhibiting a conduction type of P as a constituent may be introduced simultaneously with hydrogen.

In Step S120 of heating the first semiconductor 210, the first semiconductor 210 disposed in the reaction chamber is heated in the atmosphere of the second impurity gas. The heating temperature is in the range from 400 degrees centigrade to 800 degrees centigrade, for example. The pressure within the reaction chamber is in the range from 5 Torr to the atmospheric pressure, for example. The heating duration is in the range from 5 seconds to 50 minutes, for example. These parameters may be varied depending on the apparatus producing the semiconductor wafer 200, the capacity of the reaction chamber, the amount of the first impurity atom remaining in the reaction chamber, or the like. These heating conditions may also be designed so that the effective carrier density representing the difference between the electron density and the hole density be decreased at least on the surface of the first semiconductor 210.

For example, in the case where the second semiconductor 240 is epitaxially grown using the metal organic chemical vapor deposition (hereinafter occasionally referred to as “MOCVD”), when Si remains in the reaction chamber as first impurity atom exhibiting a conduction type of N, arsine, hydrogen, and CCl₃Br are introduced in Step S110 of introducing the gas, and heating is conducted under the condition of the temperature of 500 degrees centigrade to 800 degrees centigrade, the pressure within the reaction chamber of 0.5 Torr to the atmospheric pressure, and the heating duration of 10 seconds to 15 minutes.

As a result of conducting heating under this condition, “C” existing in CCl₃Br functions as a second impurity atom, to compensate for the donor effects of Si existing on the surface of the first semiconductor 210. This restrains the effect of the first impurity atom such as Si existing on the surface of the first semiconductor 210. For example, the existence of the second impurity atom helps prevent insulation failure from occurring on the interface between the first semiconductor 210 and the second semiconductor 240 formed thereon by the epitaxial growth method.

In Step S140 of forming the second semiconductor 240, the second semiconductor 240 is formed on the heated first semiconductor 210. Some examples of the method of forming the second semiconductor 240 are chemical vapor deposition (hereinafter referred to as “CVD”), physical vapor deposition (hereinafter referred to as “PVD”), MOCVD, and molecular beam epitaxy (hereinafter referred to as “MBE”).

When the first semiconductor 210 is a semiconductor single crystal wafer, the second semiconductor 240 may be formed on the first semiconductor 210, by the epitaxial growth method. For example, when the first semiconductor 210 is a GaAs single crystal wafer, a compound semiconductor such as GaAs, InGaAs, AlGaAs, or InGaP is formed on the first semiconductor 210 as the second semiconductor 240, by the epitaxial growth method. The second semiconductor 240 is formed to be in contact with the first semiconductor 210, for example. The semiconductor wafer 200 may include another semiconductor layer interposed between the first semiconductor 210 and the second semiconductor 240.

When the second semiconductor 240, which is made of a Group 3-5 element, is formed by MOCVD on the first semiconductor 210 of GaAs, a trialkyl compound coupled with an alkyl group having a carbon number of 1 to 3 or a hydrogen for each metal atom, or trihydride may be used as a Group 3 element material. As a Group 3 element material, for example, trimethylgallium (TMG), trimethylindium (TMI), or trimethylaluminium (TMA) may be used.

As a Group 5 element source gas, arsine (AsH₃), or alkyl arsine or phosphine (PH₃) whose at least one hydrogen atom contained in the arsine is replaced with the alkyl group having a carbon number of 1 to 4 may be used. In addition, the second semiconductor 240 may be an N-type monocarrier movement semiconductor of a Group 3-5 compound. The compound containing an impurity atom exhibiting a conduction type of N, which is used in forming the N-type monocarrier movement semiconductor, may contain silane or disilane.

In the semiconductor wafer 200 produced according to the production method according to the present embodiment, “C” existing in CCl₃Br contained in the second impurity gas compensates for the donor effects of Si remaining on the surface of the first semiconductor 210, in Step S120 of heating. As an example, the semiconductor wafer 200 may include a P-type impurity atom “C” and an N-type impurity Si having substantially the same density as “C,” on the interface between the first semiconductor 210 and the second semiconductor 240. The semiconductor wafer 200 may include an activated P-type impurity “C” and an activated N-type impurity Si having substantially the same density as the activated “C,” on the interface between the first semiconductor 210 and the second semiconductor 240.

The semiconductor wafer 200, the semiconductor wafer 300, the semiconductor wafer 400, the semiconductor wafer 1400, and the semiconductor wafer 1600 as shown in FIG. 2 to FIG. 6 may be produced, using the above-explained production method according to the present embodiment.

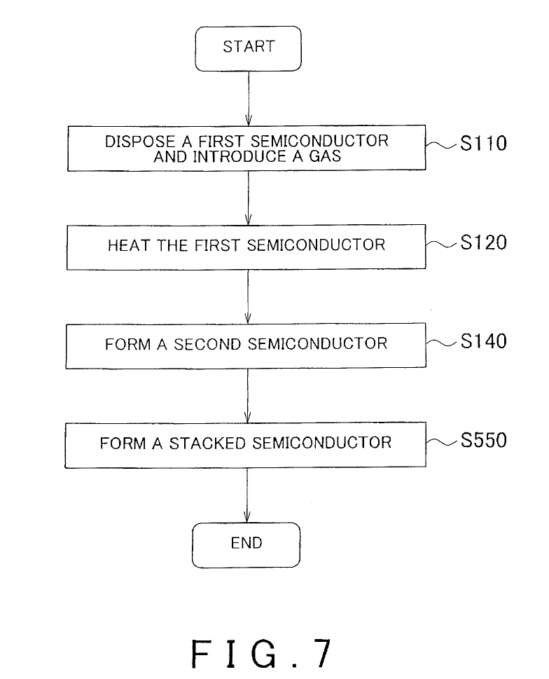

FIG. 7 shows a flowchart showing another embodiment of the method of producing a semiconductor wafer. Compared to the embodiment shown in FIG. 1, the production method according to the present embodiment further includes, after Step S140 of forming a second semiconductor, Step S550 of forming a stacked semiconductor represented by N-type semiconductor/P-type semiconductor/N-type semiconductor, or a stacked semiconductor represented by P-type semiconductor/N-type semiconductor/P-type semiconductor, either by forming the N-type semiconductor, the P-type semiconductor, and the N-type semiconductor in this order by the epitaxial growth method on the second semiconductor, or by forming the P-type semiconductor, the N-type semiconductor, and the P-type semiconductor in this order by the epitaxial growth method on the second semiconductor.

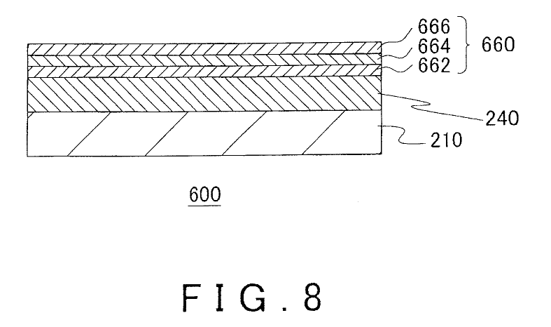

FIG. 8 shows an example of a cross section of a semiconductor wafer 600 produced by the production method according to the present embodiment. Compared to the semiconductor wafer 200, the semiconductor wafer 600 further includes a stacked semiconductor 660 on the second semiconductor 240.

The stacked semiconductor 660 includes a collector layer 662, a base layer 664, and an emitter layer 666. For example, the collector layer 662, the base layer 664, and the emitter layer 666 are a semiconductor forming a junction structure of an NPN type or a PNP type. The collector layer 662, the base layer 664, and the emitter layer 666 are semiconductor layers functioning as a collector, a base, and an emitter of a bipolar transistor.

The following explains the production method according to the present embodiment, using the semiconductor wafer 600. Note that the explanation of Steps S110 to S140 overlapping the production method in FIG. 1 is omitted. In Step S550 of forming the stacked semiconductor 660, the collector layer 662, the base layer 664, and the emitter layer 666 are sequentially formed on the second semiconductor 240, by the epitaxial growth method. For example, the epitaxial growth method may be CVD. MOCVD, or molecular beam epitaxy. For example, the above-mentioned Group 3 element material and Group 5 element material may be used in forming the stacked semiconductor 660 made of Group 3-5 elements by MOCVD on the first semiconductor 210 made of GaAs.

While forming the N-type semiconductor to be included in the stacked semiconductor 660, a gas containing an element or a compound containing an impurity atom exhibiting a conduction type of N as a constituent, is introduced in the reaction chamber. The gas contains silane or disilane, for example. While forming the P-type semiconductor to be included in the stacked semiconductor 660, a gas containing an element or a compound containing an impurity atom exhibiting a conduction type of P as a constituent, is introduced in the reaction chamber.

When the stacked semiconductor 660 is represented by N-type semiconductor/P-type semiconductor/N-type semiconductor, the first impurity gas is a gas containing an element or a compound containing an impurity atom exhibiting a conduction type of N as a constituent, having been introduced in the reaction chamber the last. When the stacked semiconductor 660 is represented by P-type semiconductor/N-type semiconductor/P-type semiconductor, the first impurity gas is a gas containing an element or a compound containing an impurity atom exhibiting a conduction type of P as a constituent, having been introduced in the reaction chamber the last.

If the next semiconductor wafer 600 is to be produced after forming the stacked semiconductor 660, a second impurity gas of a conduction type that is opposite to the conduction type of the first impurity gas having been introduced the most recently is introduced in the reaction chamber, between the time period after disposing the first semiconductor 210 in the reaction chamber and before forming the semiconductor wafer 600 to be produced first. By heating the first semiconductor 210 after introducing the second impurity gas in the reaction chamber, the first impurity attached to the first semiconductor 210 can be compensated for.

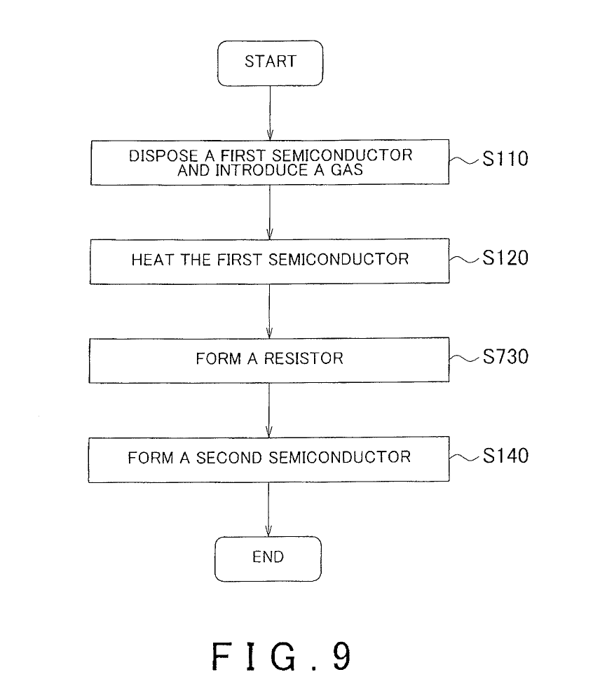

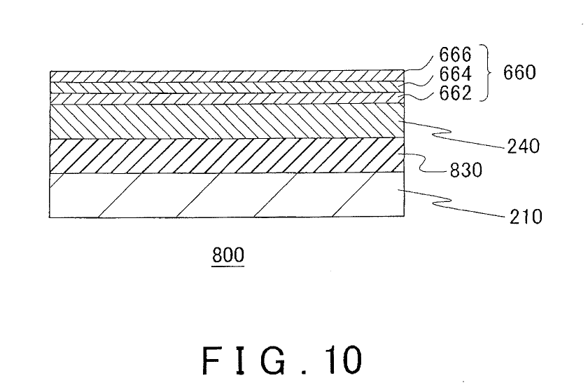

FIG. 9 shows a flowchart showing an example of the method of producing a semiconductor wafer 800 shown in FIG. 10. Compared to the embodiment shown in FIG. 1, the production method according to the present embodiment further includes Step S730 of forming a resistor 830 shown in FIG. 10, between Step S120 of heating the first semiconductor 210 and Step S140 of forming the second semiconductor 240. Likewise, the embodiment of FIG. 7 may also include Step S730 of forming the resistor 830.

FIG. 10 shows an example of a cross section of a semiconductor wafer 800 produced by the production method according to the present embodiment. Compared to the semiconductor wafer 600, the semiconductor wafer 800 further includes a resistor 830 between the first semiconductor 210 and the second semiconductor 240.

The resistor 830 is formed between the first semiconductor 210 and the second semiconductor 240. The resistor 830 may include a carrier trap. The carrier trap is a boron atom or an oxygen atom, for example. An example of the resistor 830 is compound semiconductor to which an oxygen atom is added as a carrier trap, namely, AlₓGa₁₋ₓAs (0≦x≦1) or Al_{y}In_{z}Ga_{1-y-z}P (0≦y≦1, 0≦z≦1).

By adding a carrier trap such as an oxygen atom to the compound semiconductor, the resistor 830 can have a deep trap level. When the resistor 830 has a deep trap level, the resistor 830 catches a carrier passing through the resistor 830. This helps prevent occurrence of leak current between the second semiconductor 240 and the first semiconductor 210 respectively positioned above and below the resistor 830.

The resistivity of the resistor 830 containing a carrier trap in the film thickness direction results in different values depending on the composition, the oxygen atom doping concentration and the film thickness. For example, when the resistor 830 is AlₓGa₁₋ₓAs (0≦x≦1), as the ratio of Al in the composition increases within the range in which the crystal quality is not impaired, the resistivity also increases. Practically speaking, “x” is preferably around from 0.3 to 0.5. In addition, the oxygen atom doping concentration is preferably high within the range in which the crystal quality is not impaired, and the concentration of oxygen atoms is preferably in the range of 1×10¹⁸ (cm⁻³) to 1×10²⁰ (cm⁻³). The film thickness of the resistor 830 is preferably larger within the range that would not adversely affect the growth time.

The resistor 830 may include a P-type semiconductor. The P-type semiconductor contains a plurality of Group 3-5 compound semiconductors. Two of the plurality of Group 3-5 compound semiconductors that are adjacent to each other form at least one hetero-junction selected from the group consisting of a hetero-junction between AlₓGa₁₋ₓAs (0≦x≦1) and Al_{y}Ga_{1-y}As (0≦y≦1, x<y), a hetero-junction between AlₚIn_{q}Ga_{1-p-q}P (0≦p≦1, 0≦q≦1) and AlᵣIn₅Ga₁₋ᵣ₋ₛP (0≦r≦1, 0≦s≦1, p<r), and a hetero-junction between AlₓGa₁₋ₓAs (0≦x≦1) and AlₚIn_{q}Ga_{1-p-q}P (0≦p≦1, 0≦q≦1).

For example, when the resistor 830 contains a P-type semiconductor layer AlₓGa₁₋ₓAs (0≦x≦1) in contact with the semiconductor 240 and a P-type semiconductor layer Al_{y}Ga_{1-y}As (0≦y≦0) in contact with the first semiconductor 210, and x<y, the P-type semiconductor layer Al_{y}Ga_{1-y}As has an Al composition higher than the P-type semiconductor layer AlₓGa₁₋ₓAs, and has a wider energy band gap. The band gap will be an energy barrier, to inhibit the carrier movement from the P-type semiconductor AlₓGa₁₋ₓAs towards the P-type semiconductor Al_{y}Ga_{1-y}As, thereby restraining the occurrence of leak current.

The resistor 830 may contain more P-type semiconductor layers. Each P-type semiconductor layer may have a thickness of a unit of atom, to configure a superlattice as a whole. In such a case, many energy barriers will be formed due to many hetero-junctions, preventing leak current more effectively.

The resistor 830 may have a stack structure including a plurality of P-type semiconductor layers and a plurality of N-type semiconductor layers stacked together to form a plurality of PN junctions. When the resistor 830 has such a stack structure, the plurality of PN junctions form a plurality of depleted regions to inhibit carrier movement, which enables to effectively prevent leak current.

The following explains the production method according to the present embodiment, using the semiconductor wafer 800. Note that the explanation of Steps S110, S120, and S140 overlapping the production method in FIG. 1 and FIG. 7 is omitted. In Step S730 of forming the resistor 830, the resistor 830 is formed on the first semiconductor 210. Some examples of the method of forming the resistor 830 are CVD, MOCVD, and MBE.

When the first semiconductor 210 is a semiconductor single crystal wafer, the resistor 830 is formed on the first semiconductor 210 by the epitaxial growth method. For example, when the first semiconductor 210 is a GaAs single crystal wafer, AlₓGa₁₋ₓAs (0≦x≦1), Al_{y}In_{z}Ga_{1-y-z}P (0≦y≦1, 0≦z≦1), or the like may be formed on the first semiconductor 210 by the epitaxial growth method, as the resistor 830. For example, the resistor 830 is in contact with the first semiconductor 210. The semiconductor wafer 800 may include another layer interposed between the first semiconductor 210 and the resistor 830. For example, the semiconductor wafer 800 includes a buffer layer interposed between the first semiconductor 210 and the resistor 830.

Step S730 of forming the resistor 830 may include a step of forming a P-type semiconductor contained in the resistor 830. The P-type semiconductor may be a Group 3-5 compound semiconductor formed by epitaxial growth using a Group 3 source gas containing a Group 3 element and a Group 5 source gas containing a Group 5 element. The acceptor concentration of the P-type semiconductor can be controlled by the flow rate ratio of the Group 3 source gas to the Group 5 source gas.

In the process of epitaxial growth of a Group 3-5 compound semiconductor by MOCVD, methane is generated from the organic metals by chemical reaction. A part of methane is decomposed to generate carbon. Carbon is a Group 4 element, and can be introduced into both of the sites of the Group 3 element and the Group 5 element in the Group 3-5 compound semiconductor. When carbon is introduced into the site of the Group 3 element, carbon will function as a donor, to obtain an epitaxial layer of N-type. When carbon is introduced into the site of the Group 5 element, carbon will function as an acceptor, to obtain an epitaxial layer of P-type.

That is, the epitaxial layer will be a semiconductor of either a P conduction type or an N conduction type due to the function of the carbon, and either the acceptor concentration or the donor concentration changes depending on the amount of incorporated carbon. Especially in the case of GaAs, AlGaAs, and InGaAs, carbon tends to be included as a Group 5 element, to result in P-type. High AsH₃ partial pressure makes incorporation of carbon harder, and low AsH₃ partial pressure makes incorporation of carbon easier. Therefore, the acceptor concentration of the P-type semiconductor can be controlled by adjusting the partial pressure of the source gas by adjusting the flow rate ratio of the Group 3 source gas to the Group 5 source gas.

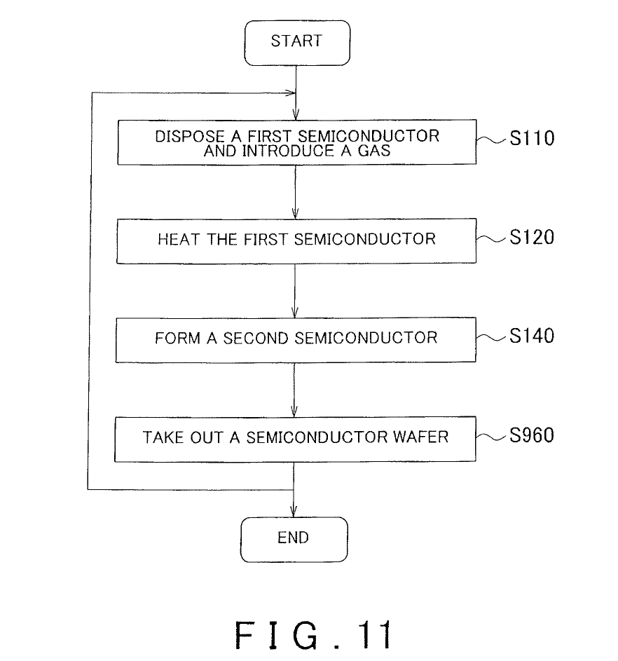

FIG. 11 shows a flowchart showing an example of the production method a semiconductor wafer 200. Compared to the embodiment shown in FIG. 1, the present embodiment further includes Step S960 of taking out the semiconductor wafer 200 from the reaction chamber, after Step S140 of forming the second semiconductor 240. The following explains the method of forming according to the present embodiment using the semiconductor wafer 200 shown in FIG. 2. The contents overlapping with the above-described embodiments will not be explained in the following description.

In Step S960 of taking out the semiconductor wafer 200, the semiconductor wafer 200, in which the second semiconductor 240 has been formed on the first semiconductor 210, is taken out of the reaction chamber. In the reaction chamber, there occasionally remains a first impurity having been introduced in the reaction chamber while forming the second semiconductor 240. When producing the next semiconductor 200, a second impurity gas can be introduced in the reaction chamber after disposing the first semiconductor 210 in the reaction chamber, which enables to alleviate the adverse effect of the first impurity remaining in the reaction chamber even without providing such processes as vacuuming.

In other words, immediately after taking out from the reaction chamber the semiconductor wafer 200 produced first, the first semiconductor 210, which is to constitute the semiconductor wafer 200 to be produced subsequently, can be disposed quickly. Thereafter, the semiconductor wafer production process can be repeated starting from Step S110 of introducing the second impurity gas in the reaction chamber.

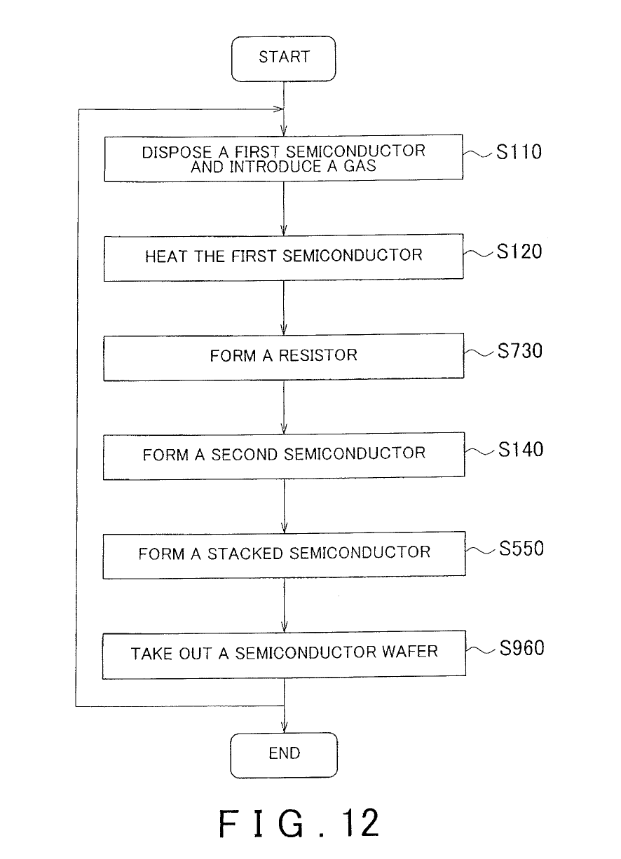

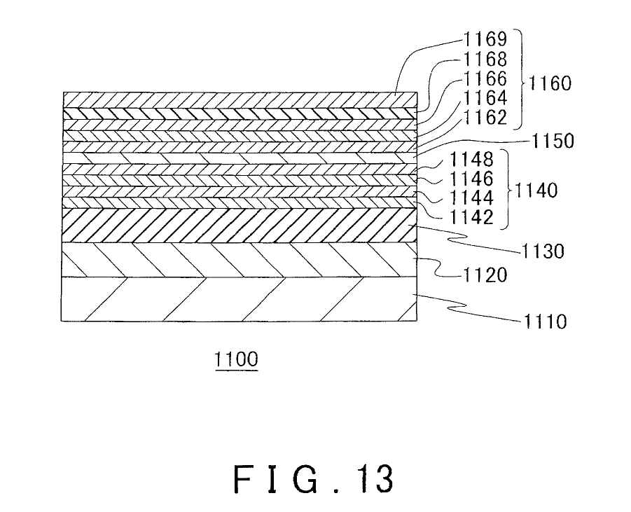

FIG. 12 shows a flowchart showing an example of the method of producing a semiconductor wafer 1100 shown in FIG. 13. The production method according to the present embodiment includes Step S110 of disposing a first semiconductor 1110 and introducing a gas, Step S120 of heating the first semiconductor 1110, Step S730 of forming a resistor 1130, Step S140 of forming a second semiconductor 1140, Step S550 of forming a stacked semiconductor 1160, and Step S960 of taking out the semiconductor wafer 1100. The process of each step may be the same as a corresponding step of each of the above-described embodiments.

FIG. 13 shows an example of a cross section of a semiconductor wafer 1100 produced by the production method shown in FIG. 12. The semiconductor wafer 1100 includes the first semiconductor 1110, the buffer layer 1120, the resistor 1130, the second semiconductor 1140, the buffer layer 1150, and the stacked semiconductor 1160. The first semiconductor 1110 corresponds to the first semiconductor 210, and the resistor 1130 corresponds to the resistor 830.

In the semiconductor wafer 1100, the first semiconductor 1110 may be a GaAs single crystal wafer, for example. As an example, the other semiconductor layers in the semiconductor wafer 1100 are Group 3-5 compound semiconductors epitaxially grown on the first semiconductor 1110 by MOCVD and lattice-matching or pseudo lattice-matching the first semiconductor 1110. The semiconductor wafer 1100 is suitable in the case of producing FET (especially HEMT and HBT) on the same wafer monolithically. The second semiconductor 1140 is a semiconductor mainly suited for forming HEMT, and the stacked semiconductor 1160 is a semiconductor mainly suited for forming HBT.

The buffer layer 1120 is a semiconductor layer functioning as a buffer for matching the lattice spacing between the semiconductor layers formed thereabove and the first semiconductor layer 1110. The buffer layer 1120 may be a semiconductor layer provided for maintaining the crystalline of the semiconductor formed thereabove. For example, the buffer layer 1120 prevents deterioration in characteristics of the semiconductor wafer 1100 attributed to the impurity atom remaining on the surface of the first semiconductor 1110. The buffer layer 1120 may be a semiconductor layer having a function of restraining leak current from the semiconductor layers formed thereabove. The buffer layer 1120 is formed by the epitaxial growth method. The material of the buffer layer 1120 may be GaAs, AlGaAs, or the like.

The second semiconductor 1140 includes a carrier-supplying semiconductor 1142, a monocarrier movement semiconductor 1144, a carrier-supplying semiconductor 1146, and a Schottky layer 1148. The monocarrier movement semiconductor 1144 functions as a channel through which one of an electron and a hole moves. The carrier-supplying semiconductor 1142 and the carrier-supplying semiconductor 1146 supply a carrier to the monocarrier movement semiconductor 1144. The Schottky layer 1148 forms a Schottky junction with the metal electrode formed in contact therewith.

The second semiconductor 1140 is a semiconductor suited to form HEMT. The carrier-supplying semiconductor 1142, the monocarrier movement semiconductor 1144, the carrier-supplying semiconductor 1146, and the Schottky layer 1148 are formed by the epitaxial growth method. The epitaxial growth method may be MOCVD, MBE, or the like. Examples of the material of the carrier-supplying semiconductor 1142, the monocarrier movement semiconductor 1144, the carrier-supplying semiconductor 1146, and the Schottky layer 1148 include GaAs, AlGaAs, or InGaAs. For example, the monocarrier movement semiconductor 1144 is an i-type InGaAs, the carrier-supplying semiconductor 1142 and the carrier-supplying semiconductor 1146 are N-type AlGaAs and the Schottky layer is AlGaAs.

The buffer layer 1150 isolates the stacked semiconductor 1160 formed thereabove from the second semiconductor 1140 formed thereunder, to prevent the mutual interaction between the stacked semiconductor 1160 and the second semiconductor 1140. The buffer layer 1150 may be formed by the epitaxial growth method, for example. The material of the buffer layer 1150 may be GaAs or AlGaAs, for example.

The stacked semiconductor 1160 includes a collector layer 1162, a base layer 1164, an emitter layer 1166, a ballast resistor layer 1168, and a contact layer 1169. The collector layer 1162, the base layer 1164, and the emitter layer 1166 are a semiconductor forming a junction structure of a NPN type or a PNP type. The collector layer 1162, the base layer 1164, and the emitter layer 1166 are semiconductor layers functioning as a collector, a base, and an emitter of a bipolar transistor.

The ballast resistor layer 1168 is a ballast resistor layer suited for an emitter ballast of a bipolar transistor. The ballast resistor layer 1168 is a high resistance region provided in the vicinity of the emitter for the purpose of restraining excessive current from flowing to the bipolar transistor. The ballast resistor layer 1168 can be used to adjust the emitter resistor to a resistance value that would not flow an excessive current, to prevent thermal runaway of the electronic element such as a transistor formed on the semiconductor wafer 1100.

The following explains the specific method of producing the semiconductor wafer 1100. When repetitively producing semiconductor wafers 1100 by the production method shown in FIG. 12, a great amount of impurity atoms used by the production process of the semiconductor wafer 1100 produced first may occasionally remain in the reaction chamber. For example, the semiconductor wafer 1100 is formed by sequentially forming, on the first semiconductor 1110, the buffer layer 1120, the resistor 1130, the second semiconductor 1140, the buffer layer 1150, and the stacked semiconductor 1160 by the epitaxial growth method. When the stacked semiconductor 1160 is a semiconductor forming a junction structure of a NPN type, a great amount of donor impurity atoms (first impurity atoms) is added to the N-type emitter layer 1166. Therefore, after forming the emitter layer 1166, the great amount of donor impurity atoms remains in the reaction chamber, as the first impurity atoms.

For example, when the donor impurity atom is Si, a great amount of Si remains in the reaction chamber. The remaining Si may have an adverse effect during the process of producing the subsequent semiconductor wafer 1100. Specifically, when the first semiconductor wafer 1110 is disposed in the reaction chamber in the subsequent process, Si remaining in the reaction chamber may occasionally attach to the surface of the first semiconductor 1110.

The attached Si may diffuse into the first semiconductor 1110 and the semiconductor wafer formed thereabove, and may function as a donor to cause an insulation failure. This may result in reduction in the device characteristic of the HEMT formed in the second semiconductor 1140. Moreover, this may result in element isolation failure between the HEMT and the HBT formed in the stacked semiconductor 1160. The production method according to the present embodiment can prevent adverse effect of Si being the first impurity atom remaining in the reaction chamber, by the following processes.

First of all, in Step S110 of disposing a first semiconductor 1110 and introducing a gas, the first semiconductor 1110 is disposed in a reaction chamber in the MOCVD furnace. Next, the reaction chamber is vacuumed, and purged using an inert gas, and gas CCl₃Br, hydrogen, and arsine are introduced to the reaction chamber. In Step S120 of heating the first semiconductor 1110, the first semiconductor 1110 is heated under the condition of the temperature of 500 degrees centigrade to 800 degrees centigrade, the pressure within the reaction chamber of 5 Torr to the atmospheric pressure, and the heating duration of 10 seconds to 15 minutes.

As a result of conducting heating under this condition, “C” existing in CCl₃Br functions as a second impurity atom, to compensate for the donor effects of Si existing on the surface of the first semiconductor 1110. This restrains the effect of the impurity atom such as Si existing on the surface of the first semiconductor 1110. For example, the existence of the second impurity atom helps prevent insulation failure from occurring between the first semiconductor 1110 and the semiconductor formed thereon by the epitaxial growth method.

Next, the buffer layer 1120 is formed on the first semiconductor 1110. As explained above, the buffer layer 1120 also prevents deterioration in characteristics of the semiconductor wafer 1100 attributed to the impurity atoms remaining on the surface of the first semiconductor 1110. The material of the buffer layer 1120 may be GaAs or AlGaAs, for example. As a Group 3 element material, trimethylgallium (TMG), trimethylaluminium (TMA), or the like may be used. Arsine (AsH₃) may be used as a Group 5 element source gas.

In Step S730 of forming a resistor 1130, the resistor 1130 is formed on the buffer layer 1120 by the epitaxial growth method. As explained above, the resistor 1130 corresponds to the resistor 830. The resistor 1130 may include a carrier trap, may include a plurality of P-type semiconductors forming a hetero-junction, or may include a plurality of N-type semiconductors and a plurality of P-type semiconductors forming a plurality of PN junctions by being stacked together. These structures help restrain leak current, to enhance the insulating characteristics between the semiconductors respectively formed above and below the resistor. The resistor 1130 may include a plurality of types of such structures.

In Step S730 of forming a resistor 1130, AlₓGa₁₋ₓAs (0≦x≦1) to which an oxygen atom is added as a carrier trap may be formed. Alternatively, a plurality of AlₓGa₁₋ₓAs having different Al compositions may be formed to form a resistor 1130 including a hetero-junction. Still alternatively, a plurality of N-type AlₓGa₁₋ₓAs (0≦x≦1) and a plurality of P-type (0≦x≦1) may be formed, to form a plurality of PN junctions.

As a Group 3 element material, trimethylgallium (TMG), trimethylaluminium (TMA), or the like may be used. As a Group 5 element source gas, arsine (AsH₃) may be used. A gas containing a second impurity atom exhibiting a conduction type of P may contain a halogenated hydrocarbon gas. The compound containing a first impurity atom used in forming an N-type semiconductor as a constituent may be silane or disilane, for example.

In Step S140 of forming a second semiconductor, a carrier-supplying semiconductor 1142, a monocarrier movement semiconductor 1144, a carrier-supplying semiconductor 1146, and a Schottky layer 1148, which are to be included in the second semiconductor 1140, are sequentially formed by the epitaxial growth method on the resistor 1130. For example, the N-type AlGaAs carrier-supplying semiconductor 1142, the i-type InGaAs monocarrier movement semiconductor 1144, the N-type AlGaAs carrier-supplying semiconductor 1146, and the AlGaAs Schottky layer are sequentially formed. As a Group 3 element material, trimethylgallium (TMG), trimethylindium (TMI), trimethylaluminium (TMA), or the like may be used. Arsine (AsH₃) may be used as a Group 5 element source gas. The compound containing, as a constituent, a first impurity atom used in forming an N-type semiconductor may be silane or disilane, for example.

The buffer layer 1150 is formed on the Schottky layer 1148 by the epitaxial growth method. As explained above, the buffer layer 1150 isolates the stacked semiconductor 1160 formed thereabove from the second semiconductor 1140 formed thereunder, to prevent the mutual interaction between the stacked semiconductor 1160 and the second semiconductor 1140. The material of the buffer layer 1150 may be GaAs or AlGaAs, for example.

In Step S550 of forming a stacked semiconductor, the collector layer 1162, the base layer 1164, and the emitter layer 1166 are sequentially formed on the buffer layer 1150 by the epitaxial growth method. The collector layer 1162, the base layer 1164, and the emitter layer 1166 are a semiconductor forming a junction structure of an NPN conduction type or a PNP conduction type.

In the stacked semiconductor 1160, a gas containing an element or a compound containing an impurity atom used in forming a P-type semiconductor as a constituent may be the same gas as the second impurity gas introduced in the reaction chamber prior to disposing and heating the first semiconductor 1110. The compound containing an impurity atom exhibiting a conduction type of N and used in forming an N-type semiconductor may be silane or disilane, for example. The ballast resistor layer 1168 and the contact layer 1169 are further formed on the emitter layer 1166.

In Step S960 of taking out the first semiconductor, the completed semiconductor wafer 1100 is taken out of the reaction chamber. Thereafter, without undergoing the process to alleviate the effect of the impurity atom in the reaction chamber, the semiconductor wafer production process can be repeated starting from Step S110 of disposing the first semiconductor 1110 to be processed next in the reaction chamber and introducing a gas in the reaction chamber.

The production method according to the present embodiment includes Step S110 of disposing the first semiconductor 1110 and introducing a gas and Step S120 of heating the first semiconductor 1110. Therefore, even when a great amount of first impurity Si used in the prior production process remains in the reaction chamber to contaminate the disposed first semiconductor 1110, the heated second impurity C existing in the CCl₃Br compensates for the donor effects of Si remaining on the surface of the first semiconductor 1110. As a result, the adverse effect of the first impurity atom such as Si existing on the surface of the first semiconductor 1110 can be restrained.

In Step S730 of forming a resistor 1130, a resistor 1130 including a carrier trap, a resistor 1130 including a plurality of P-type semiconductors forming a hetero-junction, a resistor 1130 including a plurality of P-type semiconductors a plurality of N-type semiconductors forming a plurality of PN junctions by being stacked together, or a resistor 1130 including a structure configured by a combination of these structures may be formed. By the semiconductor wafer 1100 including this resistor 1130, leak current is further restrained, to prevent insulation failure. As a result, the element isolation performance between the HEMT formed in the second semiconductor 1140 and the HBT formed in the stacked semiconductor 1160 improves.

### Embodiment Example 1

A semiconductor wafer 2100 including a stack structure shown in Table 1 was created. In Table 1, each layer number shows a reference to each semiconductor layer. Table 1 shows the material, the film thickness, the type of dopant, and the carrier concentration of each semiconductor layer. When no impurity is introduced, the type of dopant is shown as “none.”

TABLE 1

| | | | FILM | | CARRIER |
|---|---|---|---|---|---|
| LAYER | | | THICKNESS | DO- | CONCEN- |
| NUMBER | NAME | MATERIAL | [nm] | PANT | TRATION [/cm³] |
| 2170 | CONTACT LAYER | In_{0.50}Ga_{0.50}As | 100 | Si | 2.0E+19 |
| 2169 | SUB-EMITTER | GaAs | 30 | Si | 5.0E+18 |
| | LAYER | | | | |
| 2168 | BALLAST | GaAs | 100 | Si | 1.0E+16 |
| | RESISTOR LAYER | | | | |
| 2166 | EMITTER LAYER | In_{0.50}Ga_{0.50}P | 30 | Si | 3.0E+17 |
| 2164 | BASE LAYER | GaAs | 100 | C | 4.0E+19 |
| 2163 | COLLECTOR | GaAs | 600 | Si | 1.0E+16 |
| | LAYER | | | | |
| 2162 | SUB-COLLECTOR | GaAs | 600 | Si | 5.0E+18 |
| | LAYER | | | | |
| 2150 | BUFFER LAYER | GaAs | 300 | Si | 5.0E+18 |
| 2148 | SCHOTTKY | Al_{0.22}Ga_{0.78}As | 30 | Si | 5.0E+16 |
| | LAYER | | | | |
| 2146 | CARRIER- | Al_{0.22}Ga_{0.78}As | 5 | Si | 3.0E+18 |
| | SUPPLYING | | | | |
| | SEMICONDUCTOR | | | | |
| 2144 | MONOCARRIER | In_{0.25}Ga_{0.75}As | 10 | NONE | — |
| | MOVEMENT | | | | |
| | SEMICONDUCTOR | | | | |
| 2142 | CARRIER- | Al_{0.22}Ga_{0.78}As | 5 | Si | 3.0E+18 |
| | SUPPLYING | | | | |
| | SEMICONDUCTOR | | | | |
| 2140 | SECOND | Al_{0.25}Ga_{0.75}As | 100 | NONE | — |
| | SEMICONDUCTOR | | | | |
| 2130 | RESISTOR | Al_{0.30}Ga_{0.70}As | 150 | O | 2.0E+19 |
| 2120 | BUFFER LAYER | GaAs | 30 | NONE | — |
| 2110 | FIRST | SEMI- | — | — | — |
| | SEMICONDUCTOR | INSULATING | | | |
| | | GaAs WAFER | | | |

The stack of the second semiconductor layer 2140 through the Schottky layer 2148 can be used as a field effect transistor. The stack of the sub-collector 2162 through the contact layer 2170 can be used as a bipolar transistor. In other words, the semiconductor wafer 2100 is a BiFET wafer by which both of a field effect transistor and a bipolar transistor can be formed in a single wafer.

Each semiconductor layer shown in Table 1 was formed by the epitaxial growth method. In the epitaxial growth process, trimethylgallium was used as a Ga source, trimethylalminium was used as an Al source, trimethylindium was used as an In source, butyl ether was used as an O source, arsine whose concentration of monogermane is less than 0.0005 ppm was used as an As source, CBrCl₃ was used as a C source and a gas used in the heating process, and disilane was used as a Si source.

In the first process, the first semiconductor 2110 being a semi-insulating GaAs wafer was introduced in a pass box of the MOCVD reaction furnace. After lowering the pressure in the pass box, it is substituted with nitrogen. Thereafter, the first semiconductor 2110 was taken out from the pass box, moved into the reaction furnace, and then mounted therein. Then, after lowering the pressure in the reaction furnace, a hydrogen atmosphere is used to set the pressure within the reaction furnace to be 9.4 kPa.

In the second process, hydrogen at the flow rate of 20 slm and AsH₃ at the flow rate of 1250 sccm were supplied in the reaction furnace. In this state, the temperature of the reaction furnace was raised starting from the room temperature to 705 degrees centigrade. After the temperature of the reaction furnace was raised to 705 degrees centigrade, CBrCl₃ was supplied at the flow rate of 65.9 sccm, and heating was conducted for 1 minute.

In the third process, hydrogen at the flow rate of 120 slm and AsH₃ at the flow rate of 300 sccm were supplied in the reaction furnace, and the buffer layer 2120 (GaAs) was subjected to epitaxial growth in the reaction furnace at the temperature of 680 degrees centigrade until it has reached the thickness of 30 nm. Thereafter, the resistor 2130 (Al_{0.3}Ga_{0.7}As) whose O concentration is 2.0×10¹⁹(cm⁻³) was grown to the thickness of 150 nm. Further, the structures shown in Table 1 were sequentially epitaxially grown. Then, after returning the temperature in the reaction furnace to the room temperature, the semiconductor wafer 2100 in which each layer in Table 1 has been grown was taken out.

The semiconductor wafer 2100 created in the above manner is Experiment Example 1. After taking out the semiconductor wafer 2100 of Experiment Example 1, a GaAs wafer, being another first semiconductor 2110, was successively introduced in the reaction furnace, without performing cleaning (e.g., empty deposition) inside the reaction furnace or dealing with impurities having been mixed in the reaction furnace.

The semiconductor wafer 2100 created by repeating twice the series of the first process to the third process is Experiment Example 2. The semiconductor wafer 2100 created by further repeating the series of processes once is Experiment Example 3. In other words, the number of repetition of the series of processes of the first process to the third process (i.e. number of growth) was one for Experiment Example 1, two for Experiment Example 2, and three for Experiment Example 3. As the number of repetition increases, the amount of impurity atoms remaining in the reaction furnace is considered to also increase.

As a comparison example, a sample without undergoing the second process was created. Just as in Experiment Examples 1 to 3, the samples whose number of growth was 1 to 3 were created, and respectively referred to as Comparison Example 1 (one growth), Comparison Example 2 (two growths), and Comparison Example 3 (three growths).

Table 2 shows a result of measuring the withstand voltage of respective semiconductor wafers 2100 in Experiment Examples 1-3 and Comparison Examples 1-3. The withstand voltage was evaluated by measuring the current/voltage characteristic between the electrodes on the surface of the second semiconductor 2140 after removing the contact layer 2170 through the carrier-supplying semiconductor 2142 from the created semiconductor wafer 2100 by etching. Two metal thin-films having an area of 100 μm×200 μm were formed on the surface of the second semiconductor 2140 at the interval of 5 μm, as electrodes. AuGe/Ni/Au were evaporated sequentially respectively with the thicknesses of 60 nm/20 nm/150 nm, thereby completing the metal thin-film. The voltage at the current of 1.0×10⁻⁵ A was set to be the withstand voltage.

TABLE 2

| | SECOND | NUMBER OF | WITHSTAND |
|---|---|---|---|
| | PROCESS | GROWTH | VOLTAGE [V] |
| EXPERIMENT | EXIST | 1 | 65.1 |
| EXAMPLE 1 | | | |
| EXPERIMENT | EXIST | 2 | 61.8 |
| EXAMPLE 2 | | | |
| EXPERIMENT | EXIST | 3 | 54.5 |
| EXAMPLE 3 | | | |
| COMPARISON | NONE | 1 | 40.8 |
| EXAMPLE 1 | | | |
| COMPARISON | NONE | 2 | 8.8 |
| EXAMPLE 2 | | | |
| COMPARISON | NONE | 3 | 13.2 |
| EXAMPLE 3 | | | |

As shown in Table 2, the withstand voltage is higher for the Experiment Examples 1-3 compared to Comparison Examples 1-3. In other words, the heating in the second process has improved the withstand voltage.

### Embodiment Example 2

The semiconductor wafer 3100 having a stack structure shown in Table 3 was created. In Table 3, each layer number shows a reference to each semiconductor layer. Table 3 shows the material, the film thickness, the carrier type, and the carrier concentration of each semiconductor layer. If it is an intrinsic semiconductor to contain no impurity, the carrier type is shown as “i.”

TABLE 3

| | | | FILM | CAR- | CARRIER |
|---|---|---|---|---|---|
| LAYER | | | THICKNESS | RIER | CONCEN- |
| NUMBER | NAME | MATERIAL | [nm] | TYPE | TRATION [/cm³] |
| 3150 | CONTACT LAYER | GaAs | 300 | n | 5.0E+18 |
| 3148 | SCHOTTKY LAYER | Al_{0.22}Ga_{0.78}As | 30 | n | 5.0E+16 |
| 3146 | CARRIER- | Al_{0.22}Ga_{0.78}As | 5 | n | 3.0E+18 |
| | SUPPLYING | | | | |
| | SEMICONDUCTOR | | | | |
| 3144 | MONOCARRIER | In_{0.25}Ga_{0.75}As | 10 | i | — |
| | MOVEMENT | GaAs | | | |
| | SEMICONDUCTOR | GaAs | | | |
| 3142 | CARRIER- | Al_{0.22}Ga_{0.78}As | 5 | n | 3.0E+18 |
| | SUPPLYING | | | | |
| | SEMICONDUCTOR | | | | |
| 3140 | SECOND | Al_{0.25}Ga_{0.75}As | 100 | i | — |
| | SEMICONDUCTOR | | | | |
| 3130 | RESISTOR | Al_{0.30}Ga_{0.70}As | 150 | i | — |
| 3120 | BUFFER LAYER | GaAs | 30 | i | — |
| 3110 | FIRST | SEMI- | — | i | — |
| | SEMICONDUCTOR | INSULATING | | | |
| | | GaAs WAFER | | | |

The stack of the second semiconductor 3140 through the contact layer 3150 can be used as a field effect transistor. Each semiconductor layer shown in Table 3 was formed by the epitaxial growth method similar to Embodiment Example 1.

In the first process, the first semiconductor 3110 being a semi-insulating GaAs wafer was introduced in a pass box of the reaction furnace. After lowering the pressure in the pass box, it is substituted with nitrogen. Thereafter, the first semiconductor 3110 was taken out from the pass box, moved into the reaction furnace, and then mounted therein. Then, after lowering the pressure of the reaction furnace, a hydrogen atmosphere is used to set the pressure within the reaction furnace to be 9.4 kPa.

In the second process, hydrogen at the flow rate of 20 slm and AsH₃ at the flow rate of 850 sccm were supplied in the reaction furnace. In this state, the temperature of the reaction furnace was raised starting from the room temperature to 705 degrees centigrade. After the temperature of the reaction furnace was raised to 705 degrees centigrade, CBrCl₃ was supplied at the flow rate of 65.9 sccm, and the heating duration was changed in the range of 0 minute to 2.5 minutes. Experiment Examples were classified depending on the duration of CBrCl₃ supply (heating duration), such that Experiment Example 4 has a heating duration of 0.5 minute, Experiment Example 5 has a heating duration of 1.0 minute, Experiment Example 6 has a heating duration of 1.5 minutes, Experiment Example 7 has a heating duration of 2.0 minutes, and Experiment Example 8 has a heating duration of 2.5 minutes. Comparison Example 4 was set to have a heating duration of 0 minute.

In the third process, hydrogen at the flow rate of 120 slur and AsH₃ at the flow rate of 300 sccm were supplied, and the buffer layer 3120 (GaAs) was subjected to epitaxial growth in the reaction furnace whose temperature is 680 degrees centigrade until it has reached the thickness of 30 nm. Thereafter, the resistor 3130 (Al_{0.3}Ga_{0.7}As) was epitaxially grown to the thickness of 150 nm. Further, the layers shown in Table 3 were sequentially epitaxially grown. Then, after returning the temperature in the reaction furnace to the room temperature, the semiconductor wafer 3100 was taken out.

The withstand voltage was measured just as in Embodiment Example 1. Table 4 shows the measurement result of withstand voltage.

TABLE 4

| | CBrCl₃ SUPPLY | WITHSTAND |
|---|---|---|
| | TIME [min] | VOLTAGE [V] |
| COMPARISON | 0.0 | 5.7 |
| EXAMPLE 4 | | |
| EXPERIMENT | 0.5 | 6.7 |
| EXAMPLE 4 | | |
| EXPERIMENT | 1.0 | 10.3 |
| EXAMPLE 5 | | |
| EXPERIMENT | 1.5 | 11.8 |
| EXAMPLE 6 | | |
| EXPERIMENT | 2.0 | 16.1 |
| EXAMPLE 7 | | |
| EXPERIMENT | 2.5 | 22.0 |
| EXAMPLE 8 | | |

As shown in Table 4, it is confirmed that the withstand voltage becomes higher as the duration of CBrCl₃ supply (heating duration) becomes longer.

1. A method of producing a semiconductor wafer,
by repeating steps including introducing, into a reaction chamber for forming a semiconductor by crystal growth, a first impurity gas containing an element or a compound containing a first impurity atom as a constituent, thereby producing a plurality of semiconductor wafers, the method comprising, after introducing the first impurity gas:
taking out a produced semiconductor wafer;
disposing a first semiconductor in the reaction chamber;
introducing, into the reaction chamber, a second impurity gas containing an element or a compound containing, as a constituent, a second impurity atom that exhibits a conduction type opposite to the conduction type of the first impurity atom within the first semiconductor;
heating the first semiconductor in an atmosphere of the second impurity gas; and
forming a second semiconductor on the heated first semiconductor by crystal growth.

2. The method as set forth in claim 1 of producing a semiconductor wafer, wherein
the condition under which the first semiconductor is heated is set so that an effective carrier density representing the difference between the electron density and the hole density may be decreased at least on the surface of the first semiconductor.

3. The method as set forth in claim 1 of producing a semiconductor wafer, wherein
the first impurity atom is an impurity atom that exhibits a conduction type of N within the first semiconductor, and
the second impurity gas includes a P-type impurity gas containing an impurity atom that exhibits a conduction type of P within the first semiconductor.

4. The method as set forth in claim 3 of producing a semiconductor wafer, wherein
the first semiconductor or the second semiconductor is a Group 3-5 compound semiconductor, and
the P-type impurity gas contains a halogenated hydrocarbon gas.

5. The method as set forth in claim 4 of producing a semiconductor wafer, wherein
the halogenated hydrocarbon gas is CHₙX₍₄₋ₙ₎, wherein “X” is a halogen atom selected from the group consisting of Cl, Br, and I, and “n” is an integer satisfying 0≦n≦3, and when 0≦n≦2, the Xs are identical atoms or different atoms.

6. The method as set forth in claim 1 of producing a semiconductor wafer, wherein
the first semiconductor or the second semiconductor is a Group 3-5 compound semiconductor, and
the second impurity gas contains arsine and hydrogen.

7. The method as set forth in claim 6 of producing a semiconductor wafer, wherein
the second impurity gas contains an arsine source gas containing 1 ppb or less of GeH₄.

8. The method as set forth in claim 1 of producing a semiconductor wafer, wherein
the second semiconductor is a monocarrier movement semiconductor that functions as a channel through which an electron or a hole moves.

9. The method as set forth in claim 8 of producing a semiconductor wafer, wherein
the monocarrier movement semiconductor is an N-type monocarrier movement semiconductor of a Group 3-5 compound semiconductor, and
when forming the second semiconductor by crystal growth, the N-type monocarrier movement semiconductor is formed by crystal growth by introducing, into the reaction chamber, silane or disilane as a compound containing an impurity atom that exhibits the conduction type of N.

10. The method as set forth in claim 8 of producing a semiconductor wafer, further comprising:
forming, on the second semiconductor, a monocarrier movement semiconductor having a conduction type opposite to the conduction type of the second semiconductor.

11. The method as set forth in claim 1 of producing a semiconductor wafer, further comprising:
forming a stacked semiconductor represented by N-type semiconductor/P-type semiconductor/N-type semiconductor, or a stacked semiconductor represented by P-type semiconductor/N-type semiconductor/P-type semiconductor, either by forming the N-type semiconductor, the P-type semiconductor, and the N-type semiconductor in the stated order by the epitaxial growth method on the second semiconductor, or by forming the P-type semiconductor, the N-type semiconductor, and the P-type semiconductor in the stated order by the epitaxial growth method on the second semiconductor.

12. The method as set forth in claim 11 of producing a semiconductor wafer, wherein
the first impurity atom is an impurity atom that exhibits a conduction type of N within the semiconductor,
the second impurity gas includes a P-type impurity gas containing a P-type impurity atom that exhibits a conduction type of P,
the stacked semiconductor includes a base layer that functions as a base of a bipolar transistor, and
the base layer is produced by introducing a gas of the same type as the P-type impurity gas into the reaction chamber.

13. The method as set forth in claim 11 of producing a semiconductor wafer, wherein
when forming the second semiconductor by crystal growth, the N-type semiconductor is formed in the stacked semiconductor by introducing, into the reaction chamber, silane or disilane as a compound containing an impurity atom that exhibits the conduction type of N.

14. The method as set forth in claim 1 of producing a semiconductor wafer, further comprising, between heating the first semiconductor and forming the second semiconductor:
forming a resistor on the first semiconductor.

15. The method as set forth in claim 14 of producing a semiconductor wafer, wherein
the step of forming the resistor includes
forming a P-type semiconductor of a Group 3-5 compound semiconductor by epitaxial growth using a Group 3 source gas containing a Group 3 element and a Group 5 source gas containing a Group 5 element, and
when forming the P-type semiconductor, the acceptor concentration of the P-type semiconductor is controlled by the flow rate ratio of the Group 3 source gas to the Group 5 source gas.

16. The method as set forth in claim 1 of producing a semiconductor wafer, further comprising, after forming at least the second semiconductor on the first semiconductor:
taking out, from the reaction chamber, the semiconductor wafer on which at least the second semiconductor has been formed, wherein
after taking out the semiconductor wafer. 1) disposing another first semiconductor different from the first semiconductor inside the reaction chamber, and introducing the gas into the reaction chamber, 2) heating the another first semiconductor in an atmosphere of the gas, and 3) forming the second semiconductor on the heated first semiconductor are repeated without conducting a process for alleviating an effect of the impurity atom in the reaction chamber.

17. A semiconductor wafer including a first semiconductor and a second semiconductor formed on the first semiconductor, the semiconductor wafer comprising:
a P-type impurity atom and an N-type impurity atom in substantially the same density as the P-type impurity atom, on an interface between the first semiconductor and the second semiconductor.

18. The semiconductor wafer as set forth in claim 17, wherein
the P-type impurity atom and the N-type impurity atom have been activated.
